(19) United States
(12) Patent Application Publication
(10) Pub. No.: US 2025/0098207 A1
(43) Pub. Date: Mar. 20, 2025

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Tomoaki INOKUCHI, Yokoharna Kanagawa (JP); Tatsuo SHIMIZU, Shinagawa Tokyo (JP); Yusuke KOBAYASHI, Yokohama Kanagawa (JP); Shotaro BABA, Kawasai Kanagawa (JP); Hiro GANGI, Ota Tokyo (JP); Hiroki NEMOTO, Meguro Tokyo (JP); Taichi FUKUDA, Yokoharna Kanagawa (JP); Tatsuya NISHIWAKI, Yokohama Kanagawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/591,169

(22) Filed: Feb. 29, 2024

(30) Foreign Application Priority Data
Sep. 15, 2023 (JP) 2023-150123

(51) Int. Cl. H01L 29/78; H01L 29/06

(52) U.S. Cl. CPC H10D 30/635; H10D 62/126; H10D 64/647

(57) ABSTRACT

A semiconductor device includes a first conductive part, a second conductive part, a third conductive part, a first insulating part, and a semiconductor part of a first conductivity type. The second conductive part is separated from the first conductive part in a first direction. The third conductive part arranged with a portion of the second conductive part in a second direction crossing the first direction. The first insulating part includes a first insulating region located between the third conductive part and the portion of the second conductive part. The semiconductor part includes a first semiconductor region and a second semiconductor region. The first semiconductor region is located between the first conductive part and the second conductive part. The second semiconductor region is located between the first insulating region and the portion of the second conductive part. The second semiconductor region has a Schottky junction with the second conductive part.

### CROSS-REFERENCE TO RELATED APPLICATIONS

This application is based upon and claims the benefit of priority from Japanese Patent Application No. 2023-150123, filed on Sep. 15, 2023; the entire contents of which are incorporated herein by reference.

### FIELD

Embodiments relate to a semiconductor device.

### BACKGROUND

It is desirable to reduce the on-resistance of a semiconductor device such as a transistor or the like.

### BRIEF DESCRIPTION OF THE DRAWINGS

FIG. 1 is a schematic cross-sectional view illustrating a semiconductor device according to an embodiment;

FIG. 2 is a schematic cross-sectional view illustrating another semiconductor device according to the embodiment;

FIG. 3 is a schematic cross-sectional view illustrating another semiconductor device according to the embodiment;

FIG. 4 is a schematic cross-sectional view illustrating another semiconductor device according to the embodiment; and

FIGS. 5A to 5F are schematic cross-sectional views illustrating a method for manufacturing the semiconductor device according to the embodiment.

### DETAILED DESCRIPTION

A semiconductor device according to one embodiment, includes a first conductive part, a second conductive part, a third conductive part, a first insulating part, and a semiconductor part of a first conductivity type. The second conductive part is separated from the first conductive part in a first direction. The third conductive part arranged with a portion of the second conductive part in a second direction crossing the first direction. The first insulating part includes a first insulating region located between the third conductive part and the portion of the second conductive part. The semiconductor part includes a first semiconductor region and a second semiconductor region. The first semiconductor region is located between the first conductive part and the second conductive part. The second semiconductor region is located between the first insulating region and the portion of the second conductive part. The second semiconductor region has a Schottky junction with the second conductive part. A first impurity is segregated at an interface between the second conductive part and the second semiconductor region. The first conductivity type is an n-type, and the first impurity includes at least one selected from the group consisting of arsenic, phosphorus, antimony, and magnesium. Or the first conductivity type is a p-type, and the first impurity includes at least one selected from the group consisting of boron, indium, aluminum, and beryllium.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

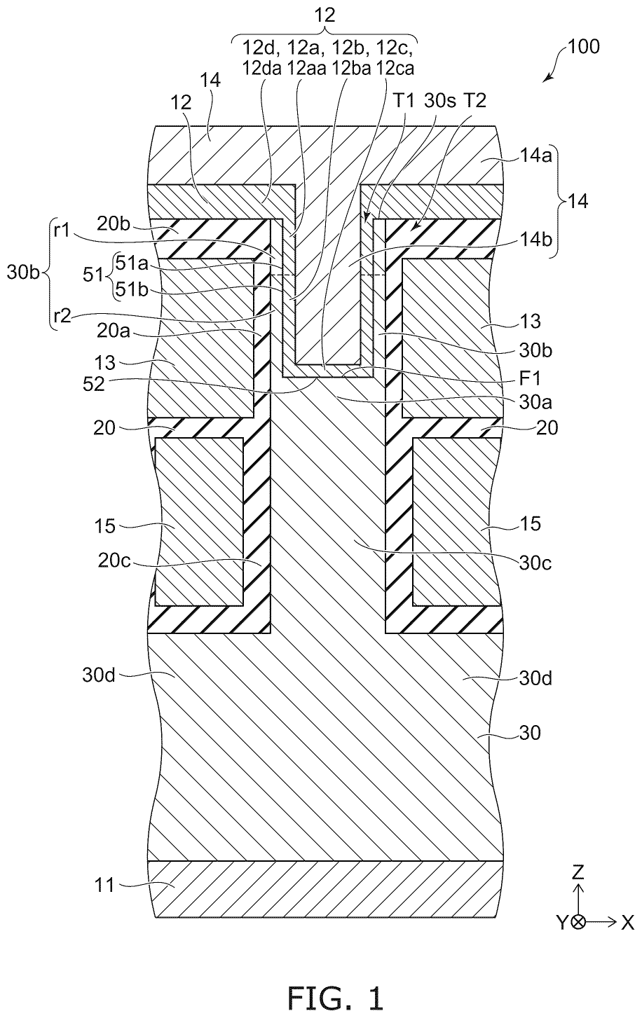

FIG. 1 is a schematic cross-sectional view illustrating a semiconductor device according to an embodiment.

As illustrated in FIG. 1, the semiconductor device 100 according to the embodiment includes a first conductive part 11, a second conductive part 12, a third conductive part 13, an insulating part 20, and a semiconductor part 30. The semiconductor device 100 may further include a fourth conductive part 14 and a fifth conductive part 15.

The second conductive part 12 is separated from the first conductive part 11 in a first direction. The first direction is taken as a Z-direction. One direction perpendicular to the Z-direction is taken as an X-direction. A direction perpendicular to the Z-direction and X-direction is taken as a Y-direction. In the first direction, the positional relationship and directional relation of the second conductive part with respect to the first conductive part 11 is called “up/above”. “Down/below” refers to the opposite of “up/above”.

The second conductive part 12 includes a first conductive region 12a, a second conductive region 12b, a third conductive region 12c, and a fourth conductive region 12d. The Z-direction position of the third conductive region 12c is between the Z-direction position of the fourth conductive region 12d and the Z-direction position of the first conductive part 11. The first conductive region 12a and the second conductive region 12b extend in the Z-direction and connect an X-direction end portion of the fourth conductive region 12d and an X-direction end portion of the third conductive region 12c. The Z-direction position of the second conductive region 12b is between the Z-direction position of the first conductive region 12a and the Z-direction position of the third conductive region 12c.

The third conductive part 13 is separated from a portion (the first conductive region 12a and the second conductive region 12b) of the second conductive part 12 in a second direction (e.g., the X-direction) crossing the Z-direction. The third conductive part 13 is arranged with another portion (the fourth conductive region 12d) of the second conductive part 12 in the Z-direction. The third conductive part 13 is between the fourth conductive region 12d and the first conductive part 11. Two configurations being arranged in one direction means that one configuration is positioned in the one direction with respect to the other configuration. When two configurations are arranged in one direction, the direction from one configuration toward the other configuration is along the one direction.

The fourth conductive part 14 is located above the second conductive part 12 and above the third conductive part 13. In other words, the second conductive part 12 and the third conductive part 13 are positioned between the fourth conductive part 14 and the first conductive part 11. The fourth conductive part 14 contacts the second conductive part 12. The fourth conductive part 14 is electrically connected with the second conductive part 12.

The fifth conductive part 15 is positioned between the first conductive part 11 and the third conductive part 13. The fifth conductive part 15 is arranged with the third conductive part 13 in the Z-direction.

The semiconductor part 30 is located between the first conductive part 11 and the second conductive part 12. The semiconductor part 30 contacts the first conductive part 11 and is electrically connected with the first conductive part 11. The semiconductor part 30 includes a first semiconductor region 30a, a second semiconductor region 30b, a third semiconductor region 30c, and a fourth semiconductor region 30d. The semiconductor part 30 is of a first conductivity type (e.g., an n-type). Although the first conductivity type is the n-type and the second conductivity type is the p-type in the example, the first conductivity type may be the p-type, and the second conductivity type may be the n-type according to the embodiment.

The first semiconductor region 30a is located between the first conductive part 11 and the second conductive part 12. The first semiconductor region 30a is arranged with the third conductive region 12c of the second conductive part 12 in the Z-direction. The first semiconductor region 30a contacts the third conductive region 12c. For example, the third conductive region 12c faces the first semiconductor region 30a in the Z-direction and has a Schottky junction with the first semiconductor region 30a.

The first semiconductor region 30a includes a counter surface F1 that faces the second conductive part 12 (the third conductive region 12c). The direction from the third conductive part 13 toward the counter surface F1 is along the second direction (e.g., the X-direction).

The second semiconductor region 30b is arranged with a portion (the first conductive region 12a and the second conductive region 12b) of the second conductive part 12 in the X-direction. The second semiconductor region 30b contacts a portion (the first conductive region 12a and the second conductive region 12b) of the second conductive part 12. For example, the second semiconductor region 30b faces a portion (the first conductive region 12a and the second conductive region 12b) of the second conductive part 12 in the X-direction, and has a Schottky junction with a portion (the first conductive region 12a and the second conductive region 12b) of the second conductive part 12.

The second semiconductor region 30b may include a first region r1 and a second region r2. The second region r2 is located between the first region r1 and the first conductive part 11. The first-conductivity-type impurity concentration (atoms/cm³) in the first region r1 is greater than the first-conductivity-type impurity concentration in the second region r2.

The first region r1 is arranged with the first conductive region 12a in the X-direction. The first region r1 has a Schottky junction with the first conductive region 12a. The second region r2 is arranged with the second conductive region 12b in the X-direction. The second region r2 has a Schottky junction with the second conductive region 12b.

The lower end (the end at the first conductive part 11 side in the Z-direction) of the first region r1 and the lower end of the first conductive region 12a overlap the third conductive part 13 in the X-direction. The upper end (the end at the side opposite to the Z-direction lower end) of the first region r1 and the upper end of the first conductive region 12a overlap a second insulating region 20b in the X-direction but do not overlap the third conductive part 13 in the X-direction. The lower end of the first region r1 and the upper end of the second region r2 overlap the third conductive part 13 in the X-direction. The entire second region r2 and the entire second conductive region 12b overlap the third conductive part 13 in the X-direction.

For example, a trench T1 is provided in a surface 30s of the semiconductor part 30. For example, the trench T1 extends in a third direction (e.g., the Y-direction) crossing the first and second directions. Multiple trenches T1 may be arranged in the X-direction with a spacing interposed. The first conductive region 12a, the second conductive region 12b, and the third conductive region 12c of the second conductive part 12 are located inside the trench T1. The second conductive part 12 is, for example, a trench contact that is electrically connected with the semiconductor part 30. For example, the first semiconductor region 30a forms the bottom surface of the trench T1. The third conductive region 12c has a Schottky contact with the bottom surface of the trench T1. For example, the second semiconductor region 30b forms the side surface of the trench T1. A portion (the first conductive region 12a and the second conductive region 12b) of the second conductive part 12 has a Schottky contact with the side surface of the trench T1.

The third semiconductor region 30c is located between the first conductive part 11 and the first semiconductor region 30a. The third semiconductor region 30c is arranged with the fifth conductive part 15 in the X-direction.

The fourth semiconductor region 30d is located between the first conductive part 11 and the third conductive part 13 (and the fifth conductive part 15). The fourth semiconductor region 30d is located between the third semiconductor region 30c and the first conductive part 11.

The insulating part 20 contacts the third conductive part 13, the fifth conductive part 15, and the semiconductor part 30. The insulating part 20 electrically insulates the third conductive part 13 and the semiconductor part 30. The insulating part 20 electrically insulates the fifth conductive part 15 and the semiconductor part 30. The insulating part 20 electrically insulates the third conductive part 13 and the fifth conductive part 15.

More specifically, the insulating part 20 includes a first insulating region 20a, a second insulating region 20b, and a third insulating region 20c. The first insulating region 20a is located between the third conductive part 13 and a portion (the first conductive region 12a and the second conductive region 12b) of the second conductive part 12. The second semiconductor region 30b is located between the first insulating region 20a and a portion (the first conductive region 12a and the second conductive region 12b) of the second conductive part 12.

The second insulating region 20b is located between the third conductive part 13 and the fourth conductive region 12d of the second conductive part 12. In the example, the fourth conductive region 12d contacts the second insulating region 20b. The third insulating region 20c is located between the third semiconductor region 30c and the fifth conductive part 15. The insulating part 20 further includes, for example, a portion located between the fourth semiconductor region 30d and the fifth conductive part 15 and a portion located between the fifth conductive part 15 and the third conductive part 13.

For example, a trench T2 is provided in the surface 30s of the semiconductor part 30. For example, the trench T2 extends in the Y-direction. Multiple trenches T2 may be arranged in the X-direction with a spacing interposed. The insulating part 20 is located inside the trench T2. The third conductive part 13 and the fifth conductive part 15 are surrounded with the insulating part 20 inside the trench T2.

The semiconductor device 100 is, for example, a MOSFET (Metal Oxide Silicon Field Effect Transistor). A current that flows between the first conductive part 11 and the second conductive part 12 (and the fourth conductive part 14) can be controlled by controlling the potential of the third conductive part 13. For example, the first conductive part 11 functions as a drain electrode. For example, the second conductive part 12 (and the fourth conductive part 14) function as a source electrode. For example, the first region r1 functions as a source region. For example, the second region r2 functions as a channel region. For example, the third conductive part 13 functions as a gate electrode. For example, the first insulating region 20a functions as a gate insulating film.

For example, a Schottky barrier is formed at the interface between the second semiconductor region 30b and the second conductive part 12 (the first conductive region 12a and the second conductive region 12b); and a depletion layer is formed in the second semiconductor region 30b (the second region r2). The potential of the third conductive part 13 controls the thickness (the X-direction distance) of the Schottky barrier and controls the carrier concentration in the second semiconductor region 30b (the second region r2). For example, when the voltage of the third conductive part 13 is not more than a threshold and the carrier concentration in the second semiconductor region 30b is low, a current substantially does not flow between the first conductive part 11 and the second conductive part 12 (and the fourth conductive part 14) via the second semiconductor region 30b. In other words, an off-state is obtained. By controlling the potential of the third conductive part 13, a current is caused to flow between the first conductive part 11 and the second conductive part 12 (and the fourth conductive part 14) via the second semiconductor region 30b when the voltage of the third conductive part 13 exceeds the threshold and causes the carrier concentration in the second semiconductor region 30b to increase. In other words, an on-state is obtained.

For example, a Schottky barrier is formed at the interface between the third conductive region 12c and the first semiconductor region 30a. The thickness (the Z-direction distance) of the Schottky barrier can be controlled by the potential of the third conductive part 13. A current does not easily flow when the Schottky barrier is thick. For example, the off-state is obtained. By controlling the potential of the third conductive part 13, the Schottky barrier becomes thin, and the tunneling current flows more easily. For example, the on-state is obtained.

For example, a transistor of a reference example has an n-p-n structure. In such a case, the gate length increases according to the width of the p-n junction. In contrast, according to the embodiment, the semiconductor part 30 is of the first conductivity type, and may not include a region of the second conductivity type. That is, a p-n junction is not formed. For example, the gate length is easily reduced thereby. Therefore, the gate capacitance is easily reduced. Also, for example, the on-resistance is easily reduced. Faster switching, turn-on loss suppression, and turn-off loss suppression can be realized. According to the embodiment, a semiconductor device can be provided in which the characteristics can be improved.

In the transistor of the reference example, a body diode is formed by a p-n junction. Therefore, there are cases where a long period of time is necessary for recovery. In contrast, according to the embodiment, a Schottky barrier is formed at the interface between the second conductive part 12 (the third conductive region 12c) and the first semiconductor region 30a. A body diode is formed thereby. Thus, recovery characteristics can be improved because the body diode is a Schottky barrier diode. The recovery can be faster.

According to the embodiment, a second impurity (hereinbelow, called the “impurity IB”) may be segregated at the interface between the second conductive part 12 and the second semiconductor region 30b. In the example (that is, when the first conductivity type is the n-type), the impurity IB includes, for example, at least one selected from the group consisting of B (boron), In (indium), Al (aluminum), and Be (beryllium). When the first conductivity type is the p-type, the impurity IB includes, for example, at least one selected from the group consisting of As (arsenic), P (phosphorus), Sb (antimony), and Mg (magnesium). The threshold voltage of the semiconductor device 100 can be increased by the segregation of such an impurity.

For example, the impurity IB that is segregated at the interface between the second conductive part 12 and the second semiconductor region 30b forms a dipole; and the effective Schottky barrier height at the interface between the second conductive part 12 and the second semiconductor region 30b is modulated. The Schottky barrier height is increased; and the threshold voltage is increased.

For example, a first segregation portion 51 at which the impurity is segregated inside the second conductive part 12 is formed between the second conductive part 12 and the second semiconductor region 30b (at the interface). When the second conductive part 12 includes the impurity IB, the impurity IB inside the second conductive part 12 is segregated at the interface between the second conductive part 12 and the second semiconductor region 30b. In other words, in such a case, the impurity IB is segregated at the first segregation portion 51. For example, the concentration (atoms/cm³) of the impurity IB in the boundary region contacting the second semiconductor region 30b of the second conductive part 12 (or at the first segregation portion 51) is greater than the concentration of the impurity IB in the inner region of the second conductive part 12 (further inward than the boundary region). When the first conductivity type is the n-type and the semiconductor part 30 is doped with the impurity IB, the dopant (the element) may be an acceptor. When the first conductivity type is the p-type and the semiconductor part 30 is doped with the impurity IB, the dopant (the element) may be a donor.

According to the embodiment, a first impurity (hereinbelow, called the “impurity IA”) may be segregated at the interface between the second conductive part 12 and the second semiconductor region 30b. In the example (that is, when the first conductivity type is the n-type), the impurity IA includes, for example, at least one selected from the group consisting of As (arsenic), P (phosphorus), Sb (antimony), and Mg (magnesium). When the first conductivity type is the p-type, the impurity IA includes, for example, at least one selected from the group consisting of B (boron), In (indium), Al (aluminum), and Be (beryllium). The on-resistance of the semiconductor device 100 can be reduced by the segregation of such an impurity.

For example, the impurity IA that is segregated at the interface between the second conductive part 12 and the second semiconductor region 30b forms a dipole and modulates the effective Schottky barrier height of the interface between the second conductive part 12 and the second semiconductor region 30b. The Schottky barrier height is reduced, and the contact resistance is reduced. The on-resistance is reduced.

When the second conductive part 12 includes the impurity IA, the impurity IA inside the second conductive part 12 is segregated at the interface between the second conductive part 12 and the second semiconductor region 30b. In other words, in such a case, the impurity IA is segregated at the first segregation portion 51. For example, the concentration (atoms/cm³) of the impurity IA in the boundary region of the second conductive part 12 contacting the second semiconductor region 30b (or the first segregation portion 51) is greater than the concentration of the impurity IA in the inner region of the second conductive part 12 (further inward than the boundary region). When the first conductivity type is the n-type and when the semiconductor part 30 is doped with the impurity IA, the dopant (the element) may be a donor. When the first conductivity type is the p-type and when the semiconductor part 30 is doped with the impurity IA, the dopant (the element) may be an acceptor.

The first segregation portion 51 may include a first segregation region 51a and a second segregation region 51b. The first segregation region 51a is positioned between the first conductive region 12a and the first region r1 (at the interface). The second segregation region 51b is positioned between the second conductive region 12b and the second region r2 (at the interface).

In the example of FIG. 1, a first conductive region 12aa that includes the impurity IA is provided as the first conductive region 12a; and a second conductive region 12ba that includes the impurity IB is provided as the second conductive region 12b.

The impurity IA is segregated at the interface between the first conductive region 12aa and the first region r1. In other words, for example, the impurity IA is segregated in the first segregation region 51a. For example, the segregated impurity forms a dipole and modulates the effective Schottky barrier height of the interface between the first conductive region 12aa and the first region r1. The Schottky barrier between the first conductive region 12aa and the first region r1 is reduced. The contact resistance between the first conductive region 12aa and the first region r1 can be reduced. For example, the concentration of the impurity IA in the boundary region of the first conductive region 12aa contacting the first region r1 (or the first segregation region 51a) is greater than the concentration of the impurity IA in the inner region of the first conductive region 12aa (further inward than the boundary region) and greater than the first-conductivity-type impurity concentration (atoms/cm³) in the semiconductor part 30 (e.g., the first region r1). The concentration of the impurity IA in the boundary region of the first conductive region 12aa contacting the first region r1 (or the first segregation region 51a) is greater than the concentration of the impurity IA in the boundary region of the second conductive region 12ba contacting the second region r2 (or the second segregation region 51b).

The impurity IB is segregated at the interface between the second conductive region 12ba and the second region r2. In other words, for example, the impurity IB is segregated in the second segregation region 51b. For example, a dipole is formed at the interface between the second conductive region 12ba and the second region r2. The Schottky barrier between the second conductive region 12ba and the second region r2 is increased by the dipole modulating the effective work function. The threshold voltage of the semiconductor device 100 can be increased. For example, the concentration of the impurity IB in the boundary region of the second conductive region 12ba contacting the second region r2 (or the second segregation region 51b) is greater than the concentration of the impurity IB in the inner region of the second conductive region 12ba (further inward than the boundary region) and greater than the concentration (atoms/cm³) of the second-conductivity-type impurity in the semiconductor part 30 (e.g., the second region r2). The second region r2 may not include the impurity IB. The concentration of the impurity IB in the boundary region of the second conductive region 12ba contacting the second region r2 (or the second segregation region 51b) is greater than the concentration of the impurity IB in the boundary region of the first conductive region 12aa contacting the first region r1 (or the first segregation region 51a).

The first conductive region 12aa may include the impurity IB; and the impurity IB may be segregated at the interface between the first conductive region 12aa and the first region r1. In other words, the concentration of the impurity IB in the boundary region of the first conductive region 12aa contacting the first region r1 (or the first segregation region 51a) may be greater than the concentration of the impurity IB in the inner region of the first conductive region 12aa (further inward than the boundary region). However, in such a case, the concentration of the impurity IA is greater than the concentration of the impurity IB in the first conductive region 12aa (the inner region). In such a case, the concentration of the impurity IA is greater than the concentration of the impurity IB in the boundary region of the first conductive region 12aa (or the first segregation region 51a).

The first conductive region 12aa may not include the impurity IB. The impurity IB may not be segregated (present) at the interface (the first segregation region 51a) between the first conductive region 12aa and the first region r1.

The second conductive region 12ba may include the impurity IA; and the impurity IA may be segregated at the interface between the second conductive region 12ba and the second region r2. In other words, the concentration of the impurity IA in the boundary region of the second conductive region 12ba contacting the second region r2 (or the second segregation region 51b) may be greater than the concentration of the impurity IA in the inner region of the second conductive region 12ba (further inward than the boundary region). However, in such a case, the concentration of the impurity IB is greater than the concentration of the impurity IA in the second conductive region 12ba (the inner region). In such a case, the concentration of the impurity IB is greater than the concentration of the impurity IA in the boundary region of the second conductive region 12ba (or the second segregation region 51b). The second conductive region 12ba may not include the impurity IA. The impurity IA may not be segregated (present) at the interface between the second conductive region 12ba and the second region r2 (the second segregation region 51b).

For example, the impurity IA may be segregated at the interface between the third conductive region 12c and the first semiconductor region 30a. In such a case, the forward voltage of the body diode formed of the third conductive region 12c and the first semiconductor region 30a can be reduced.

For example, the impurity IA that is segregated at the interface between the third conductive region 12c and the first semiconductor region 30a forms a dipole and modulates the effective Schottky barrier height of the interface between the third conductive region 12c and the first semiconductor region 30a. The Schottky barrier height is reduced, and the forward voltage of the body diode is reduced.

For example, a second segregation portion 52 in which the impurity inside the third conductive region 12c is segregated is formed between the third conductive region 12c and the first semiconductor region 30a (at the interface).

In the example of FIG. 1, a third conductive region 12ca that includes the impurity IA is provided as the third conductive region 12c. When the third conductive region 12c includes the impurity IA, the impurity IA inside the third conductive region 12c is segregated at the interface between the third conductive region 12c and the first semiconductor region 30a. In other words, in such a case, the impurity IA is segregated at the second segregation portion 52. For example, the concentration of the impurity IA in the boundary region of the third conductive region 12c contacting the first semiconductor region 30a (or the second segregation portion 52) is greater than the concentration of the impurity IA in the inner region of the third conductive region 12c (further inward than the boundary region) and greater than the first-conductivity-type impurity concentration in the semiconductor part 30 (e.g., the first semiconductor region 30a).

The third conductive region 12ca may include the impurity IB; and the impurity IB may be segregated at the interface between the third conductive region 12ca and the first semiconductor region 30a. In other words, the concentration of the impurity IB in the boundary region of the third conductive region 12ca contacting the first semiconductor region 30a (or the second segregation portion 52) may be greater than the concentration of the impurity IB in the inner region of the third conductive region 12ca (further inward than the boundary region). However, in such a case, the concentration of the impurity IA is greater than the concentration of the impurity IB in the third conductive region 12ca (the inner region). In such a case, the concentration of the impurity IA is greater than the concentration of the impurity IB in the boundary region of the third conductive region 12ca (or the second segregation portion 52).

The third conductive region 12ca may not include the impurity IB. The impurity IB may not be segregated at the interface between the third conductive region 12ca and the first semiconductor region 30a.

The fourth conductive region 12d may include at least one of the impurity IA or the impurity IB, or may not include the impurities IA and IB. In the example of FIG. 1, a fourth conductive region 12da that includes the impurity IA is provided as the fourth conductive region 12d. The fourth conductive region 12da may include the impurity IB. For example, the concentration of the impurity IA is greater than the concentration of the impurity IB in the fourth conductive region 12da.

The second conductive part 12 includes, for example, a first metallic element. The first metallic element includes at least one selected from the group consisting of Ti, W, Mo, Ta, Zr, Al, Sn, V, Re, Os, Ir, Pt, Pd, Rh, Ru, Nb, Sr, and Hf. The second conductive part 12 includes, for example, a first metal formed of the first metallic element. The second conductive part 12 includes, for example, at least one metal selected from Ti, W, Mo, Ta, Zr, Al, Sn, V, Re, Os, Ir, Pt, Pd, Rh, Ru, Nb, Sr, and Hf. The second conductive part 12 may be a metal doped with at least one of the impurity IA or the impurity IB. The metal inside the second conductive part 12 is used in the Schottky junction with the semiconductor part 30.

The fourth conductive part 14 includes, for example, a second metallic element. The second metallic element includes at least one selected from the group consisting of Al, Cu, Mo, W, Ta, Co, Ru, Ti, and Pt. The fourth conductive part 14 includes, for example, a second metal formed of the second metallic element. The fourth conductive part 14 includes, for example, at least one metal selected from the group consisting of Al, Cu, Mo, W, Ta, Co, Ru, Ti, and Pt. For example, the fourth conductive part 14 may have a stacked structure of multiple metal layers (e.g., a metal layer including Al, and a metal layer including Ti).

The work function of the second conductive part 12 (e.g., the work function of the first metal) may be greater than the work function of the fourth conductive part 14 (e.g., the work function of the second metal). For example, the second conductive part 12 includes Pt (platinum) as the metal used in the Schottky junction. The relatively high work function of the second conductive part 12 increases the Schottky barrier between the second conductive region 12b and the second region r2. The threshold voltage of the semiconductor device 100 can be increased.

On the other hand, when the work function of the second conductive part 12 is relatively high, the Schottky barrier between the first conductive region 12a and the first region r1 is increased, and the contact resistance between the first conductive region 12a and the first region r1 is increased. In contrast, in the example, the impurity IA is segregated at the interface between the first conductive region 12a and the first region r1. The contact resistance can be reduced.

When the work function of the second conductive part 12 is relatively high, the Schottky barrier between the third conductive region 12c and the first semiconductor region 30a is increased, and the forward voltage of the body diode is increased. In contrast, in the example, the impurity IA is segregated at the interface between the third conductive region 12c and the first semiconductor region 30a. The forward voltage of the body diode can be reduced.

For example, the on-resistance and the forward voltage of the body diode can be reduced while increasing the threshold voltage of the semiconductor device 100.

The third conductive part 13 and the fifth conductive part 15 may include, for example, at least one of polysilicon or a metal. The first conductive part 11 includes, for example, at least one selected from the group consisting of Al, Cu, Mo, W, Ta, Co, Ru, Ti, and Pt. The insulating part 20 includes, for example, an insulating material including at least one of silicon oxide or silicon nitride.

The semiconductor part 30 includes, for example, Si (silicon). The semiconductor part 30 includes, for example, at least one selected from the group consisting of As, P (phosphorus), and Sb (antimony) as the n-type impurity. The semiconductor part 30 may include a compound semiconductor such as a nitride semiconductor (e.g., GaN or the like), silicon carbide (SiC), an oxide semiconductor (e.g., GaO), etc.

As illustrated in FIG. 1, the fourth conductive part 14 includes a conductive upper portion 14a and a conductive lower portion 14b. A portion of the conductive upper portion 14a is arranged with the third conductive part 13 in the Z-direction. The third conductive part 13 is between the conductive upper portion 14a and the first conductive part 11. The conductive upper portion 14a is positioned on the fourth conductive region 12d and contacts the fourth conductive region 12d. That is, the fourth conductive region 12d is between the conductive upper portion 14a and the second insulating region 20b. The conductive lower portion 14b is between the conductive upper portion 14a and the first semiconductor region 30a. The conductive lower portion 14b is arranged with the third conductive part 13 in the X-direction. The conductive lower portion 14b contacts the first conductive region 12a, the second conductive region 12b, and the third conductive region 12c.

The fifth conductive part 15 may be electrically connected with the second and fourth conductive parts 12 and 14 by a not-illustrated conductive part (a wiring part, etc.). Or, the fifth conductive part 15 may be electrically connectable with the second and fourth conductive parts 12 and 14. For example, the fifth conductive part 15 functions as a field plate. For example, local concentration of the electric field is suppressed. More stable operations are obtained.

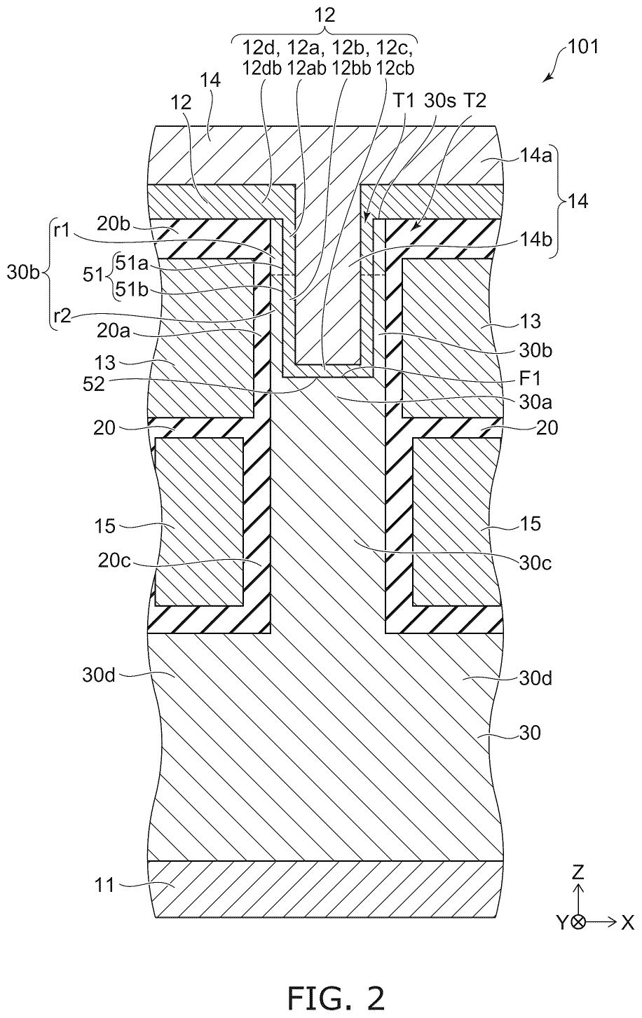

FIG. 2 is a schematic cross-sectional view illustrating another semiconductor device according to the embodiment.

The semiconductor device 101 according to the embodiment illustrated in FIG. 2 differs from the semiconductor device 100 in that the second conductive part 12 does not include the impurity IA. Otherwise, the structure of the semiconductor device 101 may be similar to that of the semiconductor device 100.

A first conductive region 12ab that includes the impurity IB is provided as the first conductive region 12a. A second conductive region 12bb that includes the impurity IB is provided as the second conductive region 12b. A third conductive region 12cb that includes the impurity IB is provided as the third conductive region 12c. A fourth conductive region 12db that includes the impurity IB is provided as the fourth conductive region 12d.

The impurity IB is segregated at the interface between the first conductive region 12ab and the first region r1 (the first segregation region 51a). The impurity IB is segregated at the interface between the second conductive region 12bb and the second region r2 (the second segregation region 51b). The impurity IB is segregated at the interface between the third conductive region 12cb and the first semiconductor region 30a (the second segregation portion 52). The impurity IA may not be segregated at the interface between the second conductive part 12 and the semiconductor part 30.

In the semiconductor device 101 as well, the impurity IB is segregated at the interface between the second conductive part 12 and the second semiconductor region 30b. As a result, the threshold voltage can be increased similarly to the semiconductor device 100.

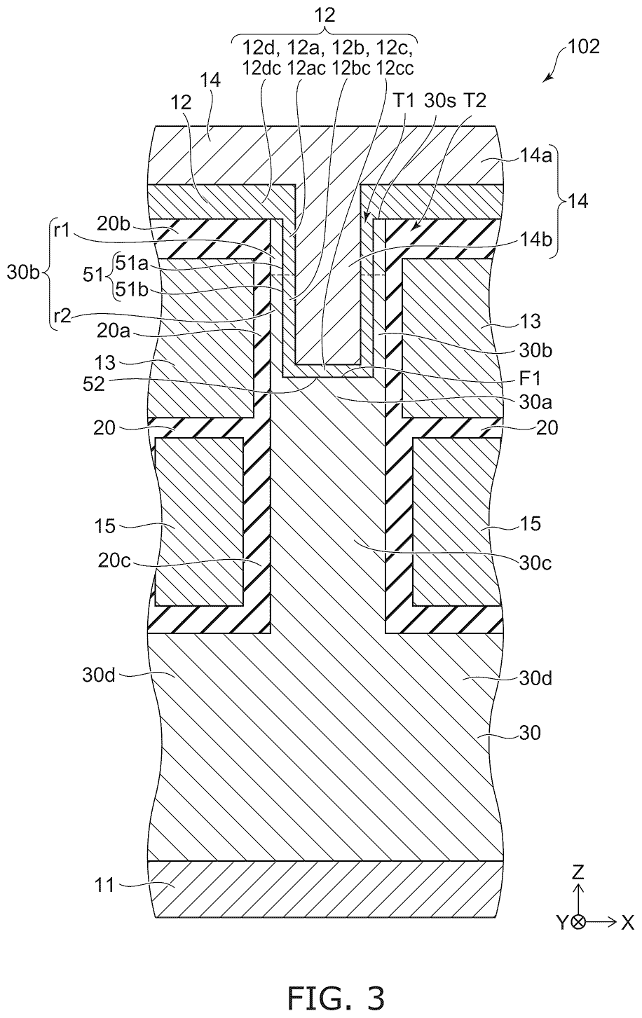

FIG. 3 is a schematic cross-sectional view illustrating another semiconductor device according to the embodiment.

The semiconductor device 102 according to the embodiment illustrated in FIG. 3 differs from the semiconductor device 100 in that the second conductive part 12 does not include the impurity IB. Otherwise, the structure of the semiconductor device 102 may be similar to that of the semiconductor device 100.

A first conductive region 12ac that includes the impurity IA is provided as the first conductive region 12a. A second conductive region 12bc is provided as the second conductive region 12b. The second conductive region 12bc may or may not include the impurity IA. A third conductive region 12cc that includes the impurity IA is provided as the third conductive region 12c. A fourth conductive region 12dc is provided as the fourth conductive region 12d. The fourth conductive region 12dc may or may not include the impurity IA. The impurity IB may not be segregated at the interface between the second conductive part 12 and the semiconductor part 30.

The impurity IA is segregated at the interface between the first conductive region 12ac and the first region r1 (the first segregation region 51a). The impurity IA is segregated at the interface between the third conductive region 12cc and the first semiconductor region 30a (the second segregation portion 52). The impurity IA may or may not be segregated at the interface between the second conductive region 12bc and the second region r2.

In the semiconductor device 102 as well, the impurity IA is segregated at the interface between the second conductive part 12 and the second semiconductor region 30b. As a result, similarly to the semiconductor device 100, the contact resistance can be reduced, and the on-resistance can be reduced. The forward voltage of the body diode can be reduced.

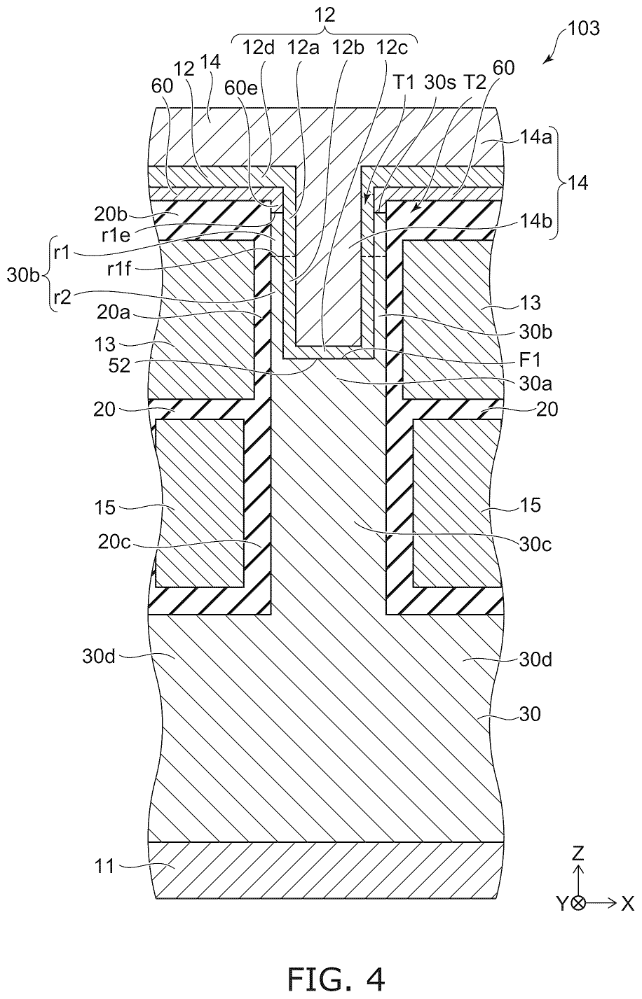

FIG. 4 is a schematic cross-sectional view illustrating another semiconductor device according to the embodiment.

The semiconductor device 103 according to the embodiment illustrated in FIG. 4 differs from the semiconductor device 100 in that a conductive film 60 is included. Otherwise, the structure of the semiconductor device 103 may be similar to the semiconductor device 100.

At least a portion of the conductive film 60 is positioned between the fourth conductive region 12d and the third conductive part 13. The conductive film 60 contacts the fourth conductive region 12d. The second insulating region 20b is positioned between the conductive film 60 and the third conductive part 13. The second insulating region 20b contacts the conductive film 60.

The conductive film 60 includes, for example, a third metallic element. When the first conductivity type is the n-type, the third metallic element includes, for example, at least one selected from the group consisting of Ti (titanium), Al, Ta (tantalum), W (tungsten), Hf (hafnium), and V (vanadium). When the first conductivity type is the p-type, the third metallic element includes, for example, at least one selected from the group consisting of Co (cobalt), Ni (nickel), Pd (palladium), Rh (rhodium), and Ir (iridium). The conductive film 60 includes, for example, a third metal formed of the third metallic element. When the first conductivity type is the n-type, the conductive film 60 includes, for example, at least one metal selected from at least one selected from the group consisting of Ti, Al, Ta, W, Hf, and V. When the first conductivity type is the p-type, the conductive film 60 includes, for example, at least one metal selected from the group consisting of Co, Ni, Pd, Rh, and Ir. Or, the conductive film 60 may include polysilicon. The polysilicon is doped with a first-conductivity-type impurity and is of the first conductivity type.

The work function of the second conductive part 12 is greater than the work function of the conductive film 60 (e.g., the work function of the third metal or polysilicon). As described above, the threshold voltage can be increased by increasing the work function of the second conductive part 12.

For example, when the second conductive part 12 includes a metal having a high work function such as Pt, etc., there are cases where the second conductive part 12 easily delaminates from the second insulating region 20b in the manufacturing processes of the semiconductor device. In contrast, by including the conductive film 60, delamination of the fourth conductive region 12d from the second insulating region 20b can be suppressed. For example, the adhesion of the conductive film 60 to the second insulating region 20b is greater than the adhesion of the fourth conductive region 12d to the second insulating region 20b. The conductive film 60 does not delaminate from the second insulating region 20b more easily than the fourth conductive region 12d. For example, the adhesion of the fourth conductive region 12d to the conductive film 60 is greater than the adhesion of the fourth conductive region 12d to the second insulating region 20b. The fourth conductive region 12d does not delaminate more easily from the conductive film 60 than from the second insulating region 20b.

An end portion 60e of the conductive film 60 contacts an upper end portion r1e of the first region r1. The conductive film 60 may have a Schottky junction with the first region r1. By the conductive film 60 contacting the first region r1, for example, the contact resistance can be reduced.

The first region r1 includes the upper end portion r1e and a lower end portion r1f. The upper end portion r1e and the lower end portion r1f are one end and another end of the first region r1 in the Z-direction. The lower end portion r1f contacts the second region r2 and is positioned between the upper end portion r1e and the first conductive part 11.

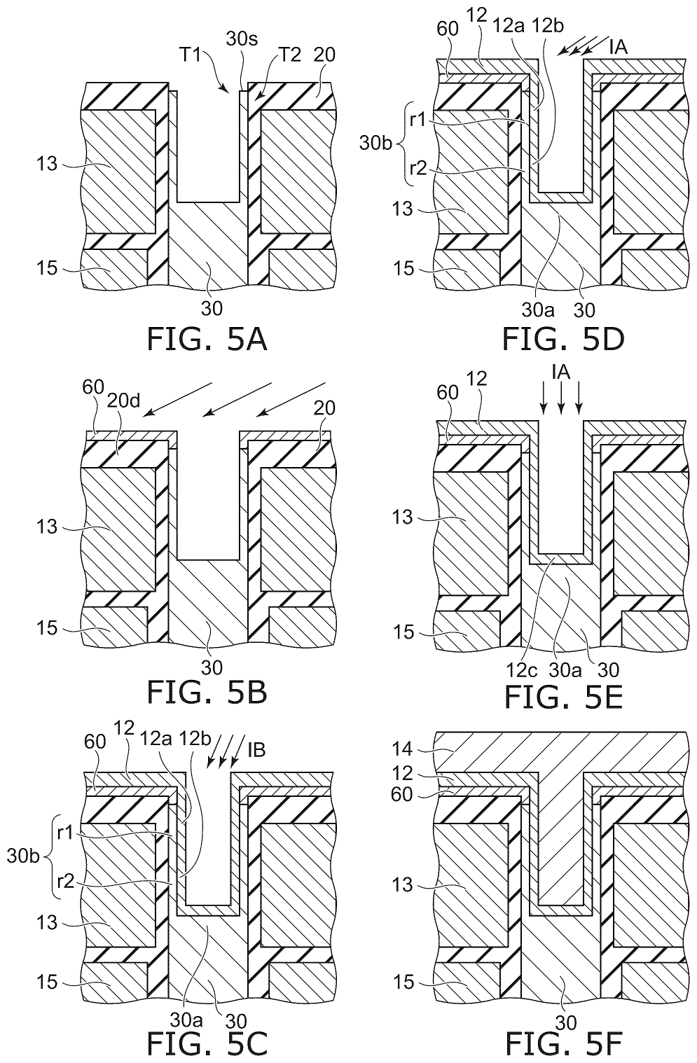

FIGS. 5A to 5F are schematic cross-sectional views illustrating a method for manufacturing the semiconductor device according to the embodiment.

FIGS. 5A to 5F illustrate a portion of the manufacturing processes of the semiconductor device 103 described with reference to FIG. 4.

As illustrated in FIG. 5A, the trench T1 and the trench T2 are provided in the surface 30s of the semiconductor part 30. The insulating part 20 and the third conductive part 13 are formed inside the trench T2.

Subsequently, as illustrated in FIG. 5B, the conductive film 60 is formed on the second insulating region 20b of the insulating part 20. For example, off-axis sputtering can be used to form the conductive film 60. In the off-axis sputtering, the material of the conductive film 60 travels in directions crossing the Z-direction and reaches the top of the second insulating region 20b. The conductive film 60 may not be formed inside the trench T1.

Then, as illustrated in FIG. 5C, a metal film (e.g., a Pt film) that is used to form the second conductive part 12 is formed on the conductive film 60 and on the inner wall of the trench T1 (on the first semiconductor region 30a and on the second semiconductor region 30b) by, for example, sputtering. For example, the impurity IB is introduced by ion implantation to at least the second conductive region 12b of the second conductive part 12. Or, the second conductive part 12 may be formed by sputtering a target doped with the impurity IB. As a result, the impurity IB is introduced to the second conductive part 12.

Subsequently, as illustrated in FIG. 5D, the impurity IA is introduced by ion implantation to the first conductive region 12a of the second conductive part 12. Then, as illustrated in FIG. 5E, the impurity IA is introduced by ion implantation to the third conductive region 12c of the second conductive part 12.

Subsequently, as illustrated in FIG. 5F, the fourth conductive part 14 is formed on the second conductive part 12 by, for example, sputtering. For example, annealing is performed at about 550° C. As a result, the impurity IA and the impurity IB are segregated at the interface between the second conductive part 12 and the semiconductor part 30.

The embodiments may include the following configurations (for example, technical proposals).

### Configuration 1

A semiconductor device, comprising:
a first conductive part;
a second conductive part separated from the first conductive part in a first direction;
a third conductive part arranged with a portion of the second conductive part in a second direction crossing the first direction;
a first insulating part including a first insulating region located between the third conductive part and the portion of the second conductive part; and
a semiconductor part of a first conductivity type, the semiconductor part including
   a first semiconductor region located between the first conductive part and the second conductive part, and
   a second semiconductor region located between the first insulating region and the portion of the second conductive part, the second semiconductor region having a Schottky junction with the second conductive part,
a first impurity being segregated at an interface between the second conductive part and the second semiconductor region,
the first conductivity type being an n-type, and the first impurity including at least one selected from the group consisting of arsenic, phosphorus, antimony, and magnesium, or
the first conductivity type being a p-type, and the first impurity including at least one selected from the group consisting of boron, indium, aluminum, and beryllium.

### Configuration 2

The device according to Configuration 1, wherein
the second conductive part includes the first impurity.

### Configuration 3

The device according to Configuration 1 or 2, wherein
the second semiconductor region includes:
   a first region; and
   a second region located between the first region and the first conductive part,
a first-conductivity-type impurity concentration in the first region is greater than a first-conductivity-type impurity concentration in the second region,
the second conductive part includes:
   a first conductive region arranged with the first region in the second direction, the first conductive region having a Schottky junction with the first region; and
   a second conductive region arranged with the second region in the second direction, the second conductive region having a Schottky junction with the second region, and
the first impurity is segregated at an interface between the first conductive region and the first region.

### Configuration 4

The device according to Configuration 3, wherein
a second impurity is segregated at an interface between the second conductive region and the second region, and
the first conductivity type is the n-type, and the second impurity includes at least one selected from the group consisting of boron, indium, aluminum, and beryllium, or
the first conductivity type is the p-type, and the second impurity includes at least one selected from the group consisting of arsenic, phosphorus, antimony, and magnesium.

### Configuration 5

The device according to Configuration 4, wherein
the first impurity is not segregated at an interface between the second conductive region and the second region.

### Configuration 6

The device according to Configuration 4 or 5, wherein
the first conductive region includes the first impurity, and
the second conductive region includes the second impurity.

### Configuration 7

The device according to any one of Configurations 1 to 6, wherein
the second conductive part further includes a third conductive region arranged with the first semiconductor region in the first direction,
the third conductive region has a Schottky junction with the first semiconductor region, and
the first impurity is segregated at an interface between the third conductive region and the first semiconductor region.

### Configuration 8

The device according to Configuration 7, wherein
the third conductive region includes the first impurity.

### Configuration 9

The device according to any one of Configurations 4 to 6, wherein
the first conductive region includes the second impurity.

### Configuration 10

The device according to any one of Configurations 1 to 9, wherein
the second conductive part includes platinum.

### Configuration 11

The device according to any one of Configurations 1 to 10, further comprising:
a fourth conductive part contacting the second conductive part,
the second conductive part being positioned between the semiconductor part and the fourth conductive part,
a work function of the second conductive part being greater than a work function of the fourth conductive part.

### Configuration 12

The device according to Configuration 11, wherein
the fourth conductive part includes a conductive upper portion and a conductive lower portion,
the third conductive part is positioned between the conductive upper portion and the first conductive part, and
the conductive lower portion is positioned between the conductive upper portion and the semiconductor part and arranged with the third conductive part in the second direction.

### Configuration 13

The device according to any one of Configurations 1 to 12, further comprising:
a conductive film,
the second conductive part including a fourth conductive region,
the third conductive part being between the first conductive part and the fourth conductive region,
the conductive film being between the fourth conductive region and the third conductive part,
the conductive film contacting the fourth conductive region,
the first insulating part being between the conductive film and the third conductive part,
the first insulating part including a second insulating region contacting the conductive film,
the first conductivity type being of the n-type, and the conductive film including at least one selected from the group consisting of titanium, aluminum, tantalum, tungsten, hafnium, vanadium, and polysilicon, or
the first conductivity type being of the p-type, and the conductive film including at least one selected from the group consisting of cobalt, nickel, palladium, rhodium, iridium, and polysilicon.

### Configuration 14

The device according to Configuration 13, wherein
a work function of the second conductive part is greater than a work function of the conductive film.

### Configuration 15

The device according to Configuration 13 or 14, wherein
the second semiconductor region includes:
   a first region; and
   a second region located between the first region and the first conductive part,
a first-conductivity-type impurity concentration in the first region is greater than a first-conductivity-type impurity concentration in the second region, and
the conductive film contacts the first region.

### Configuration 16

The device according to any one of Configurations 1 to 15, wherein
the first semiconductor region includes a counter surface arranged with the third conductive part in the second direction, and
the counter surface faces the second conductive part.

### Configuration 17

The device according to any one of Configurations 1 to 16, further comprising:
a fifth conductive part,
the semiconductor part further including a third semiconductor region located between the first conductive part and the first semiconductor region and arranged with the fifth conductive part in the second direction,
the first insulating part including a third insulating region located between the third semiconductor region and the fifth conductive part.

### Configuration 18

The device according to Configuration 17, wherein
the fifth conductive part is electrically connected with the second conductive part, or
the fifth conductive part is electrically connectable with the second conductive part.

According to embodiments, a semiconductor device can be provided in which the on-resistance can be reduced.

In this specification, being “electrically connected” includes not only the case of being connected in direct contact, but also the case of being connected via another conductive member, etc.

In the specification of the application, “perpendicular” refers to not only strictly perpendicular but also includes, for example, the fluctuation due to manufacturing processes, etc. It is sufficient to be substantially perpendicular.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in semiconductor devices from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first conductive part;
a second conductive part separated from the first conductive part in a first direction;
a third conductive part arranged with a portion of the second conductive part in a second direction crossing the first direction;
a first insulating part including a first insulating region located between the third conductive part and the portion of the second conductive part; and
a semiconductor part of a first conductivity type, the semiconductor part including
a first semiconductor region located between the first conductive part and the second conductive part, and
a second semiconductor region located between the first insulating region and the portion of the second conductive part, the second semiconductor region having a Schottky junction with the second conductive part,
a first impurity being segregated at an interface between the second conductive part and the second semiconductor region,
the first conductivity type being an n-type, and the first impurity including at least one selected from the group consisting of arsenic, phosphorus, antimony, and magnesium, or
the first conductivity type being a p-type, and the first impurity including at least one selected from the group consisting of boron, indium, aluminum, and beryllium.

2. The device according to claim 1, wherein
the second conductive part includes the first impurity.

3. The device according to claim 1, wherein
the second semiconductor region includes:
a first region; and
a second region located between the first region and the first conductive part,
a first-conductivity-type impurity concentration in the first region is greater than a first-conductivity-type impurity concentration in the second region,
the second conductive part includes:
a first conductive region arranged with the first region in the second direction, the first conductive region having a Schottky junction with the first region; and
a second conductive region arranged with the second region in the second direction, the second conductive region having a Schottky junction with the second region, and
the first impurity is segregated at an interface between the first conductive region and the first region.

4. The device according to claim 3, wherein
a second impurity is segregated at an interface between the second conductive region and the second region, and
the first conductivity type is the n-type, and the second impurity includes at least one selected from the group consisting of boron, indium, aluminum, and beryllium, or
the first conductivity type is the p-type, and the second impurity includes at least one selected from the group consisting of arsenic, phosphorus, antimony, and magnesium.

5. The device according to claim 4, wherein
the first impurity is not segregated at an interface between the second conductive region and the second region.

6. The device according to claim 4, wherein
the first conductive region includes the first impurity, and
the second conductive region includes the second impurity.

7. The device according to claim 1, wherein
the second conductive part further includes a third conductive region arranged with the first semiconductor region in the first direction,
the third conductive region has a Schottky junction with the first semiconductor region, and
the first impurity is segregated at an interface between the third conductive region and the first semiconductor region.

8. The device according to claim 7, wherein
the third conductive region includes the first impurity.

9. The device according to claim 4, wherein
the first conductive region includes the second impurity.

10. The device according to claim 1, wherein
the second conductive part includes platinum.

11. The device according to claim 1, further comprising:
a fourth conductive part contacting the second conductive part,
the second conductive part being positioned between the semiconductor part and the fourth conductive part,
a work function of the second conductive part being greater than a work function of the fourth conductive part.

12. The device according to claim 11, wherein
the fourth conductive part includes a conductive upper portion and a conductive lower portion,
the third conductive part is positioned between the conductive upper portion and the first conductive part, and
the conductive lower portion is positioned between the conductive upper portion and the semiconductor part and arranged with the third conductive part in the second direction.

13. The device according to claim 1, further comprising:
a conductive film,
the second conductive part including a fourth conductive region,
the third conductive part being between the first conductive part and the fourth conductive region,
the conductive film being between the fourth conductive region and the third conductive part,
the conductive film contacting the fourth conductive region,
the first insulating part being between the conductive film and the third conductive part,
the first insulating part including a second insulating region contacting the conductive film,
the first conductivity type being of the n-type, and the conductive film including at least one selected from the group consisting of titanium, aluminum, tantalum, tungsten, hafnium, vanadium, and polysilicon, or
the first conductivity type being of the p-type, and the conductive film including at least one selected from the group consisting of cobalt, nickel, palladium, rhodium, iridium, and polysilicon.

14. The device according to claim 13, wherein
a work function of the second conductive part is greater than a work function of the conductive film.

15. The device according to claim 13, wherein
the second semiconductor region includes:
a first region; and
a second region located between the first region and the first conductive part,
a first-conductivity-type impurity concentration in the first region is greater than a first-conductivity-type impurity concentration in the second region, and
the conductive film contacts the first region.

16. The device according to claim 1, wherein
the first semiconductor region includes a counter surface arranged with the third conductive part in the second direction, and
the counter surface faces the second conductive part.

17. The device according to claim 1, further comprising:
a fifth conductive part,
the semiconductor part further including a third semiconductor region located between the first conductive part and the first semiconductor region and arranged with the fifth conductive part in the second direction,
the first insulating part including a third insulating region located between the third semiconductor region and the fifth conductive part.

18. The device according to claim 17, wherein
the fifth conductive part is electrically connected with the second conductive part, or
the fifth conductive part is electrically connectable with the second conductive part.
